(19) United States
(12) Patent Application Publication
(10) Pub. No.: US 2018/0036940 A1
(43) Pub. Date: Feb. 8, 2018

(54) METHOD FOR PRODUCING A TRIDIMENSIONAL STRUCTURE BY 3D PRINTING

(71) Applicant: BASF SE, Ludwigshafen (DE)

(72) Inventors: Friederike FLEISCHHAKER, Ludwigshafen (DE); Valeria BEM, Mannheim (DE); Andre FUCHS, Schliengen-Obereggenen (DE)

(21) Appl. No.: 15/555,311

(22) PCT Filed: Mar. 3, 2016
(86) PCT No.: PCT/EP2016/054496

§ 371 Date: Sep. 1, 2017

(30) Foreign Application Priority Data
Mar. 3, 2015 (EP) 15157413.4

(51) Int. Cl. B29C 64/112; B33Y 10/00; G03F 7/038; G03F 7/00; G03F 7/029; B29C 64/40; B33Y 40/00

(52) U.S. Cl. CPC B29C 64/112; B29C 64/40; B33Y 10/00; B33Y 40/00; G03F 7/0037; G03F 7/029; G03F 7/038

(57) ABSTRACT

A method for producing a tridimensional structure by 3D printing comprises: (a) ejecting an object material through a first print head, the object material comprising a radically curable compound and a photoinitiator; (b) ejecting a supporting material through a second print head, the supporting material comprising a cationically polymerizable compound and a photoacid generator; (c) radiation curing the object material and the supporting material; steps (a) to (c) are repeated several times in order to form the tridimensional structure layer by layer, and the object material and the supporting material comprise at least one common boundary surface; and (d) removing the cured supporting material by treatment with an aqueous medium. The supporting material is suitable for supporting overhanging components and structures located above hollow spaces. The use of a supporting material cured by a different mechanism than the object material prevents undesirable interactions between the object material and the supporting material during curing.

### DESCRIPTION

The present invention relates to a process for producing a three-dimensional structure by three-dimensional printing using a support material which allows exact contours and a smooth surface to be obtained and allows simple removal of the support material.

Three-dimensional (3D) printing processes are usually employed for rapid prototyping. This is a one-piece production of structures, as a result of which later joining of individual parts in order to produce complex structures can be dispensed with.

The first 3D printing process was developed in 1984 by Chuck Hull who referred to his method as stereolithography, SL for short. In the SL method, a light-curing polymer applied as layer over an area in one plane is cured positionally selectively by a laser. The procedure is carried out in a bath which is filled with a liquid or paste-like base monomer of the light-sensitive polymer. The structural regions which are formed positionally selectively as a result of initiation by means of laser light in the working plane are, in a next step, moved downward into the bath by one layer thickness, so that another polymer layer can be formed in the working plane above the cured structural regions.

For example, DE 100 24 618 Al discloses such a stereolithographic process for producing three-dimensional structures, in which liquid to gel-like silicone rubbers are irradiated with IR lasers. US 2009/0224438 describes the layer-wise processing of 3D objects by means of SL processes using materials which can be photocrosslinked by means of UV or Vis light.

SL processes have, inter alia, the disadvantage that only a single photocrosslinkable material can be used for building up a three-dimensional structure. Limits in respect of the elastic structural properties, for example, are also imposed thereby.

A further 3D printing process was developed at the Massachusetts Institute of Technology. Here, for example, pulverulent polymers are applied in layers to a support plate. Binders are squirted by means of an ink jet printer onto the places which are to be solidified in each layer.

Furthermore, the photopolymer jetting process (also known as PolyJet process) can be used for producing three-dimensional structures. Here, a printing block having one or more printing heads moves back and forth in the manner of a line printer along an x axis and leaves behind thin photopolymer layers on a building platform. Each layer is cured immediately after application by means of UV lamps which are installed directly on the printing block.

Photopolymer jetting allows fabrication of three-dimensional parts with a high degree of geometric freedom and variable materials properties, for example elasticity, using, optionally, a plurality of different materials.

Thus, U.S. Pat. No. 6,658,314 B1 describes a process for producing a three-dimensional structure, in which two photopolymers are mixed in different ratios in order to influence the elasticity of the three-dimensional structure in a targeted manner.

However, the production of overhanging structures and hollow spaces is not readily possible since, owing to the layer-wise construction, overhanging constituents and structures above hollow spaces would not be joined to the layer underneath. However, such structures can be stabilized by application of not only the object material but also a support material which can usually be removed in an aqueous medium after manufacture.

Thus, for example, U.S. Pat. No. 6,863,859 B2 describes a composition which comprises a heat-sensitive polymer and is suitable as support material and a process for producing three-dimensional structures using the support material composition, in which the support material is removed in an aqueous medium after production.

US 2010/0256255 A1 describes support materials which comprise at least one dendritic oligomer, at least one monofunctional monomer and a reactive amine.

WO 201²/₁16047 A1 describes support materials which comprise at least one ethoxylated fatty alcohol and the use thereof in 3D printing processes. WO 01/68375 A2 describes support materials which comprise at least one reactive component such as acrylates or vinyl ethers and a photoinitiator, and the use thereof in 3D printing processes.

It is usual for both the object material and the support material to be free-radically crosslinkable or polymerizable. As a result, mixed products can be formed in regions in which the object material and support material bound on one another. This can result in unsharp boundaries between object material and support material and the component has to be, for example, mechanically after-treated in order to remove support material residues and smooth the surface of the three-dimensional structure.

It is therefore an object of the present invention to provide a process for producing a three-dimensional structure by three-dimensional printing using a support material which allows exact contours and a smooth surface to be obtained and allows complete and simple removal of the support material.

The object is achieved by a process for producing a three-dimensional structure by means of three-dimensional printing, which comprises the following steps:

a) ejection of an object material from a first printing head, where the object material comprises a free-radically curable compound and a photoinitiator;

b) ejection of a support material from a second printing head, where the support material comprises a cationically polymerizable compound and a photoacid generator; and

c) radiation curing of the object material and the support material;

where the steps a) to c) are repeated a plurality of times in order to form the three-dimensional structure in a layerwise manner, and the object material and the support material have at least one common interface; and removal of the cured support material by treatment with an aqueous medium.

The use of a support material which cures according to a different mechanism than that of the object material prevents unwanted interactions between the object material and the support material upon curing. As a result, subsequent treatment of the surface of the three-dimensional structure to remove residues of the support material is unnecessary or necessary only to a greatly reduced extent.

It is also possible to eject the support material in the form of a separating layer. The actual support is then effected by a secondary support material. This should advantageously be performed as a support function in cases where the cured support material is too soft an account of its glass transition temperature or its melting point. In one embodiment, the process therefore comprises the following steps:

b) ejection of the support material in the form of a separating layer; and

b′) ejection of a secondary support material from a third printing head;

where the steps a), b), b′) and c) are repeated a plurality of times in order to form the three-dimensional structure in a layerwise manner and the support material and the secondary support material have at least one common interface;

d) removal of the cured support material and the secondary support material by treatment with an aqueous medium.

The viscosity of the object material, the pre-support materials and, if present, the secondary support material is preferably less than 20 mPas at 70° C. The viscosity is usually from 8 to <20 mPas at 70° C., particularly preferably from 8 to 15 mPas at 70° C. Since droplet formation in the printing head is possible only up to a particular viscosity, a higher viscosity would be disadvantageous.

Object Material

In one embodiment, the object material comprises at least one free-radically curable compound. The free-radically curable compound has at least one ethylenically unsaturated double bond. Suitable free-radically curable compounds comprise monofunctional compounds (compounds having one ethylenically unsaturated double bond), polyfunctional compounds (compounds having two or more ethylenically unsaturated double bonds), including ethylenically unsaturated prepolymers. The free-radically curable compound preferably comprises at least one polyfunctional compound. Owing to their low viscosity, monofunctional compounds can be concomitantly used, e.g. as reactive diluents.

Examples of monomeric monofunctional compounds comprise (meth)acrylic compounds and vinyl compounds.

(Meth)acrylic compounds include:

C₁-C₁₈-Alkyl (meth)acrylates, such as methyl acrylate, ethyl acrylate, butyl acrylate, 2-ethylhexyl acrylate, isobornyl acrylate, methyl methacrylate, ethyl methacrylate, butyl methacrylate; C₂-C₁₈-hydroxyalkyl (meth)acrylates, such as 2-hydroxyethyl (meth)acrylate, 2-hydroxyethyl methacrylate, 4-hydroxybutyl acrylate; C₁-C₁₀-alkoxy-C₂-C₁₈-alkyl (meth)acrylates, such as 2-methoxyethyl (meth)acrylate, 2-ethoxyethyl (meth)acrylate; aryloxyalkyl (meth)acrylates, such as phenoxyethyl methacrylate, p-cumylphenoxyethyl methacrylate; C₇-0₂₀-aralkyl (meth)acrylates, such as benzyl (meth)acrylate; C₂-C₇-heterocyclyl(meth)acrylates, such as tetrahydrofurfuryl (meth)acrylate; C₂-C₇-heterocyclyl-C₂-C₁₀-alkyl (meth)acrylates such as 2-N-morpholinoethyl (meth)acrylate, 2-(2-oxo-1-imidazolidinyl)ethyl (meth)acrylate; C₂-C₁₀-aminoalkyl (meth)acrylates such as 2-aminoethyl (meth)acrylate; mono- or di-C₁-C₁₀-alkyl-C₂-C₁₀-aminoalkyl (meth)acrylates such as 2-(dimethylamino)ethyl (meth)acrylate, 2-(diethylamino)ethyl (meth)acrylate, 2-(diisopropylamino)ethyl (meth)acrylate, 2-(tert-butylamino)ethyl (meth)acrylate; (meth)acrylonitrile; (meth)acrylamide; C₂-C30-alkyl(meth)acrylamides such as N-n-butyl(meth)acrylamide, N-tert-butyl(meth)acrylamide, N-octyl(meth)acrylamide, N-lauryl(meth)acrylamide, N-1-methylundecyl(meth)acrylamide, N-2-ethylhexyl(meth)acrylamide and N-tert-octyl(meth)acrylamide; C₂-C₁₈-hydroxyalkyl(meth)acrylamides such as N-hydroxyethyl(meth)acrylamide, N-[tris(hydroxymethyl)methyl](meth)acrylamide; C₁-C₁₀-alkoxy-C₁-C₁₈-alkyl(meth)acrylamides such as N-(3-methoxypropyl)(meth)acrylamide, N-(butoxymethyl)(meth)acrylamide, N-(isobutoxymethyl)(meth)acrylamide; C₂-C₇-heterocyclyl(meth)acrylamides such as N-tetrahydrofurfuryl(meth)acrylamide; C₂-C₇-heterocyclyl-C₂-C₁₀-alkyl(meth)acrylamides such as N-(2-N-morpholinoethyl)(meth)-acryamide, N-(2-(2-oxo-1-innidazolidinypethyl)(meth)acrylamide; C₂-C₁₀-aminoalkyl(meth)acrylamides such as N-(3-aminopropyl)(meth)acrylamide; and mono- or di-C₁-C₁₀-alkyl-C₂-C₁₀-aminoalkyl(meth)acrylamides such as N-[2-(dimethylamino)-ethyl](meth)acrylamide, N[3-(dimethylamino)propyl](meth)acrylamide.

The vinyl compounds include vinyl esters such as vinyl acetate; N-vinylamides such as N-vinylpyrrolidone; vinylaromatics such as styrene, alkylstyrenes and halostyrenes; and vinyl halides such as vinyl chloride and vinylidene chloride.

Examples of polyfunctional compounds comprise, for example, esters of polyols with ethylenically unsaturated carboxylic acids such as acrylic acid, methacrylic acid, crotonic acid, itaconic acid, cinnamic acid, maleic acid, fumaric acid and unsaturated fatty acids such as linoleic acid, linolenic acid or oleic acid. Preference is given to acrylic acid and methacrylic acid.

Suitable polyols comprise aromatic and in particular aliphatic and cycloaliphatic polyols. Examples of aromatic polyols comprise hydroquinone, 4,4′-dihydroxybiphenyl, 2,2-di(4-hydroxyphenyl)propane and also novolacs and resols. Examples of aliphatic and cycloaliphatic polyols comprise alkylenediols which preferably have from 2 to 12 carbon atoms, e.g. ethylene glycol, 1,2- or 1,3-propanediol, 1,2-, 1,3- or 1,4-butanediol, pentanediol, hexanediol, octanediol, dodecanediol, diethylene glycol, triethylene glycol, polyethylene glycols having preferred molar masses of from 200 to 1500 g/mol, 1,3-cyclopentanediol, 1,2-, 1,3- or 1,4-cyclohexanediol, 1,4-dihydroxymethylcyclohexane, glycerol, tris(β-hydroxyethypamine, trimethylolethane, trimethylolpropane, pentaerythritol, dipentaerythritol and sorbitol. Further suitable polyols comprise, for example, polymers and copolymers which comprise hydroxyl groups in the polymer chain or in side chains, e.g. polyvinyl alcohol and copolymers thereof, and also polyhydroxyalkyl methacrylates and copolymers thereof. Oligoesters comprising hydroxyl end groups are likewise suitable polyols.

The polyols can be partly or fully esterified with one or more different unsaturated carboxylic acids, with the free hydroxyl groups in partial esters possibly having been modified, e.g. etherified or esterified with other carboxylic acids.

Examples of esters comprise trimethylolpropane triacrylate, trimethylolethane triacrylate, trimethylolpropane trimethacrylate, trimethylolethane trimethacrylate, tetramethylene glycol dimethacrylate, triethylene glycol dimethacrylate, tetraethylene glycol diacrylate, pentaerythritol diacrylate, pentaerythritol triacrylate, pentaerythritol tetraacrylate, dipentaerythritol diacrylate, dipentaerythritol triacrylate, dipentaerythritol tetraacrylate, dipentaerythritol pentaacrylate, dipentaerythritol hexaacrylate, tripentaerythritol octaacrylate, pentaerythritol dimethacrylate, pentaerythritol trimethacrylate, dipentaerythritol dimethacrylate, dipentaerythritol tetramethacrylate, tripentaerythritol octamethacrylate, pentaerythritol diitaconate, dipentaerythritol trisitaconate, dipentaerythritol pentaitaconate, dipentaerythritol hexaitaconate, ethylene glycol diacrylate, hexamethylene glycol diacrylate, 1,3-butanediol diacrylate, 1,3-butanediol dimethacrylate, 1,4-butanediol diitaconate, sorbitol triacrylate, sorbitol tetraacrylate, modified pentaerythritol triacrylate, sorbitol tetramethacrylate, sorbitol pentaacrylate, sorbitol hexaacrylate, oligoester acrylates and methacrylates, bisphenol A diacrylates, glycerol diacrylates and triacrylates, 1,4-cyclohexanediacrylate, 4,4′-bis(2-acryloyloxyethoxy)diphenylpropane, bisacrylates and bismethacrylates of polyethylene glycol having a molar mass in the range from 200 to 1500 g/mol, or mixtures thereof.

Further suitable esters comprise dipropylene glycol diacrylate, tripropylene glycol diacrylate, 1,6-hexanediol diacrylate, ethoxylated glycerol triacrylate, propoxylated glycerol triacrylate, ethoxylated trimethylolpropane triacrylate, propoxylated trimethylolpropane triacrylate, ethoxylated pentaerythritol tetraacrylate, propoxylated pentaerythritol triacrylate, propoxylated pentaerythritol tetraacrylate, ethoxylated neopentyl glycol diacrylate, propoxylated neopentyl glycol diacrylate.

Further examples of polyfunctional compounds comprise amides of the above or other unsaturated carboxylic acids with aromatic, cycloaliphatic and aliphatic polyamines which preferably have from 2 to 6, particularly preferably from 2 to 4, amino groups. Examples of such polyamines comprise ethylenediamine, 1,2- or 1,3-propylenediamine, 1,2-, 1,3- or 1,4-butylenediamine, 1,5-pentylenediamine, 1,6-hexylenediamine, octylenediamine, dodecylenediamine, 1,4-diaminocyclohexane, isophoronediamine, phenylenediamine, bisphenylenediamine, di-β-aminoethyl ether, diethylenetriamine, triethylenetetramine, di(β-aminoethoxy)ethane or di(β-aminopropoxy)ethane. Further suitable polyamines are polymers and copolymers which may have further amino groups in the side chains, and oligoamides having terminal amino groups. Examples of such unsaturated amines comprise: methylenebisacrylamide, 1,6-hexamethylenebisacrylamide, diethylenetriaminetrismethacrylamide, bis(methacrylamidopropoxy)ethane, p-methacrylamidoethyl methacrylate and N-[(β-hydroxyethoxy)ethyl]acrylamide.

Further examples of polyfunctional compounds comprise vinyl acrylate, divinylbenzene, divinyl succinate, dially phthalate, triallyl phosphate, triallyl isocyanurate, tris(2-acryloyl-ethyl) isocyanurate and dicyclopentadienyl acrylate.

Suitable prepolymers are polymers which comprise ethylenically unsaturated groups in the main chain or as side groups or are terminated therewith, e.g. unsaturated polyesters, polyamides and polyurethanes and copolymers thereof, polybutadiene and butadiene copolymers, polyisoprene and isoprene copolymers, polymers and copolymers which comprise (meth)acrylate groups in the side chains, and also mixtures of one or more polymers of this type.

Suitable unsaturated polyesters and polyamides are prepared, for example, from maleic acid and diols or diamines. The polyesters and polyamides can also be prepared from dicarboxylic acids and ethylenically unsaturated diols or diamines, in particular relatively long-chain diols or diamines having, for example, from 6 to 20 carbon atoms. Further examples of polyesters comprise unsaturated polyester resins which are generally prepared from maleic acid, phthalic acid and one or more diols. Suitable polyesters also comprise alkyd resins. Suitable polyamides are, for example, condensates of polyamines and unsaturated dimeric fatty acids.

Examples of unsaturated polyurethanes comprise those which are prepared from saturated diisocyanates and unsaturated diols or from unsaturated diisocyanates and saturated diols.

Butadiene, which serves as monomer for polybutadiene or butadiene copolymers, generally polymerizes in such a way that an ethylenically unsaturated group remains as part of the main chain or side chain. The same applies to polyisoprene, which serves as monomer for polyisoprene and isoprene copolymers. Examples of suitable comonomers comprise, in each case, olefins such as ethene, propene, butene, hexene, (meth)acrylates, acrylonitrile, styrene and vinyl chloride.

Polymers which comprise (meth)acrylate groups in the side chain are known by those skilled in the art. They comprise, for example, reaction products of novolac-based epoxy resins and (meth)acrylic acid, homopolymers or copolymers of vinyl alcohol or the hydroxyalkyl derivatives thereof which have been esterified with (meth)acrylic acid, and homopolymers and copolymers of (meth)acrylates which have been esterified with hydroxyalkyl (meth)acrylates.

Copolymers which comprise (meth)acrylate groups as side groups can be obtained, for example, by functionalization of copolymers by means of (meth)acrylic acid. The functionalization of copolymers is preferably carried out using (meth)acrylic acid. In these compounds, the ethylenically unsaturated double bonds are preferably present in the form of (meth)acryloyl groups. Preference is given to at least two polymerizable double bonds being present in the form of (meth)acryloyl groups in the molecule. The average molar mass of these compounds can, for example, be in the range from 300 to 10 000 g/mol, preferably in the range from 800 to 10 000 g/mol.

Prepolymers can also be terminated with ethylenically unsaturated compounds. For example, maleate-terminated oligomers having polyester, polyurethane, polyether and polyvinyl ether main chains are used. Further examples of ethylenically unsaturatedly terminated prepolymers comprise urethane (meth)acrylates, epoxy(meth)acrylates and acrylated epoxy resins.

Further particularly suitable compounds are urethane (meth)acrylates which can be obtained by reaction of polyisocyanates with hydroxyalkyl (meth)acrylates and optionally chain extenders such as diols, polyols, diamines, polyamines or dithiols or polythiols. These include urethane oligomers which bear terminal and/or lateral (meth)acrylic groups. Urethane oligomers are conventionally prepared by reaction of an aliphatic or aromatic diisocyanate with a divalent polyether or polyester, particularly typically a polyoxyalkylene glycol such as polyethylene glycol. Such oligomers typically have from 4 to 10 urethane groups. The isocyanate-terminated polyurethane polymer resulting from this reaction is then reacted with (meth)acrylic acid, a (meth)acrylamide or a (meth)acrylic ester having a hydroxyl group, in particular with a hydroxyalkyl (meth)acrylate such as hydroxypropyl acrylate (HPA), hydroxypropyl methacrylate (HPMA), hydroxybutyl acrylate (HBA) or hydroxybutyl methacrylate (HBMA), preferably with hydroxyethyl acrylate (HEA) or hydroxyethyl methacrylate (HEMA), or with a monohydroxy poly(meth)acrylate of a polyol, preferably of glycerol or trimethylolpropane, to give a polyurethane (meth)acrylate.

A suitable urethane (meth)acrylate is, for example, UDMA (an addition product of 2-hydroxyethyl methacrylate and 2,2,4-trimethylhexamethylene diisocyanate). Polyether urethane acrylate oligomers or polyester urethane acrylate oligomers are, for example, Ebecryl 284 and CN 982, CN 982610 and CN 988 B88 from Sartorner.

Further particularly suitable compounds are epoxy (meth)acrylates which can be obtained by reaction of epoxides with (meth)acrylic acid. Possible epoxides are, for example, epoxidized olefins, aromatic glycidol ethers or aliphatic glycidol ethers, preferably those of aromatic or aliphatic glycidol ethers. A suitable epoxy (meth)acrylate is, for example, bis-GMA (an addition product of methacrylic acid and bisphenol A diglycidyl ether).

The free-radically curable compound is preferably present in the object material in an amount of at least 50% by weight, particularly preferably at least 70% by weight, based on the weight of the object material.

The object material further comprises a photoinitiator. Photoinitiators are photoactive substances which on illumination with UV light form free radicals and can thus initiate free-radical crosslinking or polymerization.

As photoinitiators, it is possible to use photoinitiators known to those skilled in the art, e.g. those mentioned in “Advances in Polymer Science”, Volume 14, Springer Berlin 1974 or K. K. Dietliker, Chemistry and Technology of UV and EB-Formulation for Coatings, Inks and Paints, Volume 3; Photoinitiators for Free Radical and Cationic Polymerization, P. K. T. Oldring (Eds), SITA Technology Ltd, London.

Possibilities are, for example, monoacylphosphine or bisacylphosphine oxides as described, for example, in EP-A 7 508, EP-A 57 474, DE-A 196 18 720, EP-A 495 751 or EP-A 615 980, for example 2,4,6-trimethylbenzoyldiphenylphosphine oxide (Lucirin TPO), bis(2,4,6-trimethyllDenzoyl)phenylphosphine oxide (Irgacure 819), ethyl 2,4,6-trimethylbenzoylphenylphosphinate, benzophenones, hydroxyacetophenones, phenylglyoxylic acid and derivatives thereof or mixtures of these photoinitiators. As examples, mention may be made of benzophenone, acetophenone, acetonaphthoquinone, methyl ethyl ketone, valerophenone, hexanophenone, [alpha]-phenylbutyrophenone, p-morpholinopropiophenone, dibenzosuberone, 4-morpholinobenzophenone, 4-morpholinodeoxybenzoin, p-diacetylbenzene, 4-aminobenzophenone, 4′-methoxyacetophenone, β-methylanthraquinone, tert-butyl-anthraquinone, anthraquinonecarboxylic esters, benzaldehyde, [alpha]-tetralone, 9-acetylphenanthrene, 2-acetylphenanthrene, 10-thioxanthenone, 3-acetylphenanthrene, 3-acetylindole, 9-fluorenone, 1-indanone, 1,3,4-triacetylbenzene, thioxanthen-9-one, xanthen-9-one, 2,4-dimethylthioxanthone, 2,4-diethylthioxanthone, 2,4-diisopropylthioxanthone, 2,4-dichlorothioxanthone, benzoin, benzoin isobutyl ether, chloroxanthenone, benzoin tetrahydropyranyl ether, benzoin methyl ether, benzoin ethyl ether, benzoin butyl ether, benzoin isopropyl ether, 7-H-benzoin methyl ether, benz[de]anthracen-7-one, 1-naphthaldehyde, 4,4′-bis(dimethylamino)benzophenone, 4-phenylbenzophenone, chlorobenzophenone, Michler's ketone, 1-acetonaphthone, 2-acetonaphthone, 1-benzoylcyclohexan-1-ol, 2-hydroxy-2,2-dimethylacetophenone, 2,2-dimethoxy-2-phenylacetophenone, 2,2-diethoxy-2-phenylacetophenone, 1,1-dichloroacetophenone, 1-hydroxyacetophenone, acetophenone dimethyl ketal, o-methoxybenzophenone, triphenylphosphine, tri-o-tolylphosphine, benz[a]anthracene-7,12-dione, 2,2-diethoxyacetophenone, benzil ketals such as benzil dimethyl ketal, 2-methyl-1-[4-(methylthio)phenyl]-2-morpholinopropan-1-one, anthraquinones such as 2-methylanthraquinone, 2-ethylanthraquinone, 2-tert-butylanthraquinone, 1-chloro-anthraquinone, 2-amylanthraquinone and 2,3-butanedione.

Among the photoinitiators mentioned, preference is given to phosphine oxides, α-hydroxyketones and benzophenones. It is also possible to use mixtures of various photoinitiators.

In general, the photoinitiator is present in the object material in an amount of from 0.001 to 15% by weight, preferably from 0.01 to 10% by weight, based on the total weight of the object material.

In one embodiment, the object material further comprises a sensitizer by means of which the photoinitiator is excited. Suitable sensitizers are normally used in combination with at least one of the above photoinitiators. A preferred combination comprises a sensitizer selected from among thioxanthone, benzophenone, coumarin and derivatives thereof. Sensitizers are preferably used in an amount in the range from 0.001 to 15% by weight, preferably from 0.01 to 10% by weight, based on the total weight of the object material.

The object material can further comprise a stabilizer which suppresses spontaneous or thermally uncontrolled polymerization of the object material. Suitable stabilizers are, for example, hydroquinones or monomethylhydroquinones. Stabilizers are preferably concomitantly used in an amount of less than 500 ppm, more preferably less than 200 ppm, more preferably less than 100 ppm.

The object material can appropriately comprise a thickener for setting a suitable viscosity. This suitable thickness are pyrogenic silica and laminar silicates.

The object material can further comprise other customary constituents such as antifoams, fluidizers, plasticizers, surface-active substances, pigments, dyes, dispersants and the like.

Object materials which are suitable for the purposes of the invention are commercially available. They comprise, for example, the Vero materials, Durus materials, Tango materials and FullCure materials, e.g. FullCure 720, produced by Stratasys.

Support Material

The support material comprises a cationically polymerizable compound. For the present purposes, cationically polymerizable compounds are compounds in which the tendency for cationic polymerization is much greater than that for free-radical polymerization.

In the cationic polymerization, a reactive cation, i.e. a Lewis or Brönsted acid, which reacts in an initiating reaction with the double bond of a reactive unit is used as initiator. This is followed by growth reactions in which the cation resulting from the initiating reaction adds onto a further monomer to once again form a cation.

The cationically polyrnerizable compounds preferably do not comprise any ethylenically unsaturated radicals.

As cationically polymerizable compounds, it is possible to use cationically polymerizable monomers and macromonomers such as epoxides, oxetanes, oxazolines, lactones, lactams, vinyl ethers, furans, cyclic ketene acetals, spiroorthocarbonates or bicyclic ortho esters. The support material preferably comprises a cationically polymerizable compound selected from among epoxides, vinyl ethers, lactones, lactams, oxetanes and oxazolines, more preferably from among oxazolines.

In order to ensure the requisite water-solubility of the polymers of the cationically polymerizable compounds, the cationically polymerizable compounds are optionally substituted by hydrophilic units. Examples of hydrophilic units include carboxylic acid, carboxylic ester, carboxamide, sulfonic acid, sulfonic ester, sulfonamide, sulfinic acid, sulfenic acid, sulfoxide, nitrile, ketone, aldehyde, alcohol, amine, ether and imine units.

Suitable epoxides are, in particular, glycidyl ethers or cycloaliphatic epoxides such as bisphenol A diglycidyl ether, 3,4-epoxycyclohexylmethyl 3,4-epoxycyclohexane-carboxylate and bis(3,4-epoxycyclohexylmethyl) adipate.

Suitable oxetanes comprise 3-ethyl-3-hydroxymethyloxetane, hydrophilically substituted 2-ethylhexyloxetane, 3-ethyl-3[[(3-ethyloxetan-3-yl)methoxy]methyl]oxetane, hydrophilically substituted 1,10-decanediylbis(oxymethylene)bis(3-ethyloxetane) or 3,3-(4-xylylenedioxy) bis(methyl-3-ethyloxetane).

Examples of commerically available oxetanes include Aron Oxetane OXT-101, OXT-212, OXT-121 and OXT-221, produced by Toagosei Co., Ltd.

Suitable oxazolines are selected from among 2-methyl-2-oxazoline, 2-ethyl-2-oxazoline, 2-hydroxymethyl-2-oxazoline, 2-hydroxyethyl-2-oxazoline, hydrophilically substituted 2-phenyloxazoline, hydrophilically substituted 2-decyloxazoline, 2-(3′-methoxymonoethylene glycol)propyl-2-oxazoline, 2-(3′-methoxytriethylene glycol)propyl-2-oxazoline and 2-(2′-N-pyrrolidonyl-ethyl)-2-oxazoline. Particularly preferred is 2-ethyl-2-Oxazoline.

The cationic polymerization of oxazolines proceeds via the ring-opening polymerization shown below:

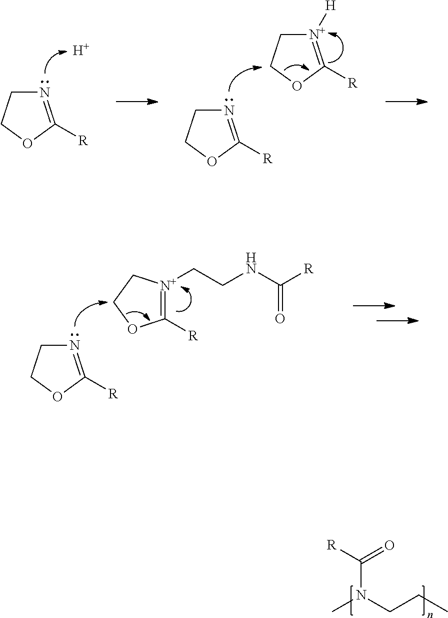

Suitable lactones are selected from among β-propiolactone, γ-butyrolactone, δ-valerolactone, ε-caprolactone and glucono-1,5-lactone.

Suitable lactams are selected from among β-propiolactam, γ-butyrolactam, δ-valerolactam, E-caprolactam and N-methyl-2-pyrrolidone.

Suitable vinyl ethers comprise optionally hydrophilically substituted C₁₋₈-alkyl vinyl ethers, diethylglycol divinyl ether and triethylglycol divinyl ether.

Suitable furans comprise furan, optionally hydrophilically substituted 3-(C₁₋₈-alkyl)furans and 4-(C₁₋₈-alkyl)furans.

Suitable cyclic ketene acetals comprise 2-methylene-1,3-dioxepane, 2-phenyl-4-methylene-1,3-dioxolane.

Suitable spiroorthocarbonates comprise hydrophilically substituted 2-methylene-1,4,6-trioxaspiro[2.2]nonane and 3,9-dimethylene-1,5,7,11-tetraoxaspiro[5.5]undecane.

In a preferred embodiment, the support material comprises at least 80% by weight of the cationically polymerizable compound, particularly preferably at least 90% by weight, based on the total weight of the support material.

The support material comprises a photoacid generator. For the purposes of the present invention, a photoacid generator is a compound which on irradiation with short-wavelength light, for example UV irradiation, liberates a reactive cation (i.e. a Lewis or Brönsted acid).

Suitable photoacid generators comprise ionic and nonionic photoacid generators.

Ionic photoacid generators are derived from stable organic onium salts, in particular those having nitrogen, phosphorus, oxygen, sulfur, selenium or iodine as central atom of the cation. Preference is given to aromatic sulfonium and iodonium salts with complex anions, phenacylsulfonium salts, hydroxyphenylsulfonium salts and sulfoxonium salts.

Such ionic photoacid generators comprise, for example, the commercial products having the names Irgacure 250, Irgacure PAG 290 and GSlD26-1 from BASF SE; Cyracure UVI-6990 and Cyracure UVI-6974 from Union Carbide; Degacure K1 85 from Degussa; Optomer SP-55, Optomer SP-150 and Optomer SP-170 from Adeka; GE UVE 1014 from General Electric, SarCat CD 1012; and SarCat KI-85, SarCat CD 1010 and SarCat® CD 1011 from Sartomer.

Nonionic photoacid generators comprise compounds which on photolysis liberate carboxylic acids, sulfonic acids, phosphoric acids or hydrogen halides, for example nitrobenzyl esters, sulfonic acid derivatives, phosphate esters, phenolsulfonate esters, diazonaphthoquinone and N-hydroxyimidosulfonate. These can be used either alone or in combination. Preference is given to sulfonic acid derivatives. Compared to ionic photoacid generators, nonionic photoacid generators are soluble in a wide range of solvents.

Such nonionic photoacid generators comprise, for example, N-hydroxy-5-norbornene-2,3-dicarboximide perfluoro-1-butanesulfonate, N-hydroxynaphthalimide triflate and 2-(4-methoxystyryl)-4,6-bis(trichloromethyl)-1,3,5-triazine, and also the commercial products having the names Irgacure PAG 103, Irgacure PAG 121, Irgacure PAG 203, CGI 725 and CGI 1907 from BASF SE.

It is also possible to use organic silicon compounds which on UV irradiation in the presence of an aluminum-comprising organic compound liberate a silanol.

Further suitable photoacid generators are those which are excited by means of a sensitizer. Sensitizers are preferably used in an amount in the range from 0.001 to 15% by weight, preferably from 0.01 to 10% by weight, based on the total weight of the object material.

Suitable sensitizers are usually used in combination with at least one of the above photoacid generators. Preferred sensitizers are polycyclic aromatic compounds such as anthracene, naphthalene and derivatives thereof (see also U.S. Pat. No. 6,313,188, EP 0 927 726, WO 2006/073021, U.S. Pat. No. 4,997,717, U.S. Pat. No. 6,593,388 and WO 03/076491). A preferred combination comprises a sensitizer selected from among polycyclic aromatic compounds and a nonionic photoacid generator.

In a preferred embodiment of the present invention, the photoacid generator is present in the support material in an amount of from 0.001 to 15% by weight, particularly preferably from 0.01 to 10% by weight.

In a preferred embodiment, the support material is water-based. Particularly preferably the support material is free of nonaqueous solvents.

The support material can appropriately comprise a thickener for setting a suitable viscosity. Suitable thickeners are pyrogenic silica and laminar silicates.

The support material can further comprise other customary constituents such as antifoams, fluidizers, plasticizers, surface-active substances, pigments, dispersants and the like.

Secondary Support Material

It is also possible to eject the support material in the form of a separating layer. The actual support is then provided by a secondary support material, with the support material and the secondary support material having at least one common interface.

The object material and the secondary support material preferably do not have any common interface. In this case, object material and secondary support material can be crosslinked or polymerized by the same mechanism, for example both object material and secondary support material are free-radically crosslinkable or polymerizable. Possible secondary support materials are all support materials which are known for 3D printing and after radiation curing are soluble in an aqueous medium.

After radiation curing of the object material and the support material, the secondary support material can be removed together with the cured support material by treatment with an aqueous medium, preferably an alkaline aqueous medium.

The secondary support material is advantageously a conventional support material for 3D printing processes. In these cases, the secondary support material is generally cheaper than the support material. Application of the support material as separating layer then allows, firstly, exact contours and a smooth surface to be obtained and at the same time allows an inexpensive process.

The secondary support material can also be a wax-like material which after ejection solidifies by cooling, e.g. polyethylene glycols or ethoxylated fatty alcohols having suitable melting points.

The printing materials of the present invention can also comprise suitable auxiliaries such as accelerators, absorbers, mechanical stabilizers, pigments, dyes, viscosity modifiers, agents for reducing the surface tension and wetting agents and antioxidants.

Radiation Curing

The radiation curing of the object material, the support material and optionally the secondary support material (hereinafter referred to as the printing materials) is effected by means of high-energy light, e.g. UV light or electron beams, preferably UV light. Radiation curing can be carried out at elevated temperatures. However, the temperature is preferably below the glass transition temperature T_{g} of the printing materials.

For the present purposes, radiation curing refers to the crosslinking or polymerization of the free-radically crosslinkable or cationically polymerizable compounds of the printing materials as a result of electromagnetic and/or particle radiation, preferably UV light in the wavelength range of λ=200 to 700 nm and/or electron beams in the range from 150 to 300 keV and particularly preferably at a radiation dose of at least 80 mJ/cm², preferably from 80 to 3000 mJ/cm².

Suitable radiation sources for radiation curing are, for example, low-pressure, intermediate-pressure and high-pressure mercury lamps and also fluorescence tubes, pulsed lamps, metal halide lamps, electronic flash devices, by means of which radiation curing without photoinitiator is possible, or excimer lamps. Radiation curing is effected by action of high-energy radiation, i.e. UV radiation or daylight, preferably light in the wavelength range of λ=200 to 700 nm, particularly preferably λ=200 to 500 nm and very particularly preferably λ=250 to 400 nm, or by irradiation with high-energy electrons (electron beam; 150 to 300 keV). For example, high-pressure mercury vapor lamps, lasers, pulsed lamps (flash), halogen lamps, LED lamps or excimer lamps serve as radiation sources. The radiation dose which is usually sufficient for crosslinking in UV curing is in the range from 80 to 3000 mJ/cm².

Of course, it is also possible to use a plurality of radiation sources. e.g. from two to four, for curing. These can also radiate in different wavelength ranges.

Irradiation can also be carried out in the absence of oxygen, e.g. under an inert gas atmosphere. Suitable inert gases are preferably nitrogen, noble gases, carbon dioxide or combustion gases.

When curing is effected by means of UV irradiation instead of electron beams, it goes without saying that the printing materials each comprise at least one photoinitiator or photoacid generator which is activable in a wavelength range of the radiation used for irradiation.

3D Printing

The process of the invention is appropriately carried out in a photopolymer jet printing apparatus. Here, a printing block having at least two printing heads moves back and forth over a building platform and leaves thin layers of photopolymerizable printing materials behind on the building platform. The amount of printing materials ejected and thus the thickness of the layers is set via a regulator which is coupled to a computer-aided construction (CAD) system. Each layer is cured immediately after application by means of UV lamps which are installed directly on the printing block. The budding platform is appropriately lowered with increasing height of the printed structure, so that the printing block moves exclusively along the x axis during printing.

In a preferred embodiment of the printing head arrangement, this has a plurality of printing nozzles which are arranged along a line and through which the in each case photopolymerizable printing material can be ejected in a uniformly distributed manner. The printing heads preferably have at least 20, particularly preferably from 50 to 500, printing nozzles. During discharge of the material, the printing head arrangement is preferably moved orthogonally to the linear arrangement of the individual printing nozzles relative to the working plane. A printing head arrangement configured in this way makes it possible to dispense with stocking of a liquid photocrosslinkable material within a bath, as is customary, for example, in the SL process.

In an embodiment of the present invention, object material and support material are applied to one substrate. A stiff or flexible substrate is preferably used as substrate; in particular, the substrate can be made of a polymer material. In one embodiment, the substrate can be a plastic sheet, plastic film, membrane, glass, metal, semimetal, nonwoven or paper, preferably of biocompatible, in particular biodegradable, material.

In one embodiment of the present invention, the substrate is, after conclusion of the repeated execution of the process sequences a) to c) or a), b), b′) and c), particularly preferably after step d), separated off from the resulting three-dimensional structure, in particular by means of chemical, physical or biological degradation.

In a further embodiment of the present invention, the substrate remains part of the structure produced after conclusion of the repeated execution of the process sequences a) to c) or a), b), b′) and c), particularly preferably after step d), and thus becomes an integral constituent of the three-dimensional structure.

Removal of the Support Material

The cured support material and optionally the cured secondary support material are removed by treatment with an aqueous medium. Here, the solidification mechanism of the support material or the secondary support material is reversed and the support material or the secondary support material is dissolved. The aqueous medium is appropriately an aqueous alkali medium, e.g. aqueous sodium hydroxide solution having, for example, a concentration of from 0.1 to 2 M. As an alternative, an aqueous acidic medium is suitable. The structure obtained can be freed of the cured support material by dipping into or leaching with the aqueous medium. As an alternative, the structure can be blasted with the aqueous medium.

The support material is preferably water-based. The support material is particularly preferably free of nonaqueous solvents. In these cases, the pH of the aqueous medium by means of which the cured support material or the cured secondary support material are removed appropriately differs by at least 1, preferably at least 2, very particularly preferably at least 3, from the pH of the support material.

The invention will be illustrated with the aid of the accompanying drawing and the following examples.

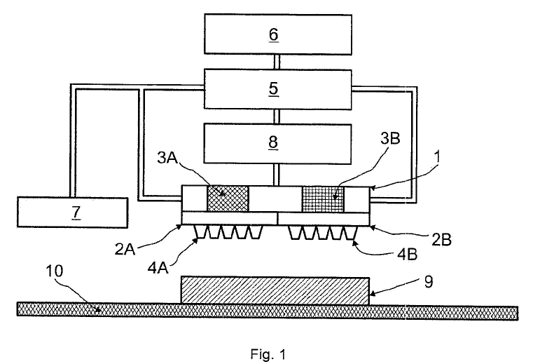

FIG. 1 schematically shows an apparatus suitable for carrying out the process of the invention.

In FIG. 1, the apparatus comprises a printing block 1 which comprises two or more printing heads 2, which are individually designated as 2A and 2B, and at least two storage vessels or dispensers 3 which comprise different printing materials and are individually designated as 3A (object material) and 3B (support material). The dispensers 3 can be in each case be charged via lines to external reservoirs (not shown in FIG. 1). Other printing materials and other combinations of printing materials can be used. The pressure heads 2 each have a plurality of nozzles as are used, for example, in inkjet processes through which the printing materials 3A and 3B are ejected.

In one embodiment of the present invention, the first dispenser comprising the object material 3A is connected to a first set of nozzles, designated as 4A, and the second dispenser comprising support material 3B is connected to a second set of nozzles, designated as 4B. Accordingly, object material 3A is ejected through the nozzles 4A and support material 3B is ejected through the nozzles 4B. In some embodiments, the three-dimensional printing system optionally comprises (not shown) more than two printing heads, with each printing head being connected to a dispenser comprising object material or support material and being able to be controlled in order to eject the material in the respective dispenser by means of the nozzles of the printing head. Use is optionally made of more than one object material, in which case each object material is ejected using a different dispenser and printing head.

The printing apparatus additionally comprises a regulator 5, a computer-aided construction (CAD) system 6, a UV curing unit 7 and optionally a positioning device 8. The regulator 5 is coupled to the CAD system 6, the UV curing unit 7, the optional positioning device 8, the printing heads 2 and each of the dispensers 3 which comprise the printing materials. Regulation can be effected by units different from those shown, e.g. one or more separate units.

The three-dimensional structure 9 to be produced is produced in layers using at least one of the object materials 3A on a printing platform 10 having an adjustable height, with the height of each layer typically being able to be regulated by the discharge of the individual inkjet nozzles 4A being set selectively.

### EXAMPLES

### Example 1

Helios FullCure 525 photopolymer jet ink (comprising glycerol propoxylate (1PO/OH) triacrylate, CAS No. 52408-84-1, and a photoinitiator; object material) from Stratasys was applied in a silicone mold as bead having a diameter of about 1 cm. Immediately thereafter a bead having a diameter of about 1 cm of 2-ethyl-2-oxazoline (CAS No. 10431-98-8) with 1% by weight of Irgacure PAG 103 (support material) was applied in such a way that the two materials were in contact at an interface. The beads had a thickness of about 0.5 to 1 mm.

The materials were then illuminated by means of an Hg lamp (365 nm) at 30 mW/cm² for 15 minutes. Cured support material was removed in an aqueous-alkaline medium (1 M NaOH). For this purpose, the aqueous-alkali medium was introduced into the mold, whereupon the cured support material dissolved within a few minutes. The aqueous-alkali medium was taken out and the object which remained was washed with water. The object had no visible residues of support material.

### Example 2

Helios FullCure 525 photopolymer jet ink (comprising glycerol propoxylate (1PO/OH) triacrylate, CAS No. 52408-84-1, and a photoinitiator; object material) from Stratasys was applied in a silicone mold as bead having a diameter of about 1 cm. Immediately thereafter a bead having a diameter of about 1 cm of 2-ethyl-2-oxazoline (CAS No. 10431-98-8) with 1% by weight of Irgacure PAG 103 (support material) was applied in such a way that the two materials were in contact at an interface. Next to the ethyloxazoline, furthermore a bead having a diameter of about 1 cm of Support FullCure 705 (comprising glycerol propoxylate(1PO/OH) triacrylate, CAS No. 52408-84-1, and bis(2,4,6-trimethylbenzoyl)phenylphosphine oxide (Irgacure 819), CAS No. 162881-26-7, secondary support material) from Stratasys was applied in such a way that the materials were in contact at a second interface. The beads had a thickness of from about 0.5 to 1 mm.

The materials were then illuminated by means of an Hg lamp (365 nm) at 30 mW/cm² for 15 minutes. Cured support material and secondary support maternal was removed in an aqueous-alkaline medium (1 M NaOH). For this purpose, the aqueous-alkali medium was introduced into the mold, whereupon the cured support material and the cured secondary support material dissolved within a few minutes. The aqueous-alkaline medium was taken out and the object which remained was washed with water. The object had no visible residues of support material.

1.-10. (canceled)

11. A process for producing a three-dimensional structure by three-dimensional printing, which comprises the following steps:
a) ejection of an object material from a first printing head, where the object material comprises a free-radically curable compound and a photoinitiator;
b) ejection of a support material from a second printing head, where the support material comprises a cationically polymerizable compound and a photoacid generator; and
c) radiation curing of the object material and the support material;
where the steps a) to c) are repeated a plurality of times in order to form the three-dimensional structure in a layerwise manner and the object material and the support material have at least one common interface; and
d) removal of the cured support material by treatment with an aqueous medium.

12. The process according to claim 11, comprising:
b) ejection of the support material in the form of a separating layer;
b′) ejection of a secondary support material from a third printing head;
wherein the steps a), b), b′) and c) are repeated a plurality of times in order to form the three-dimensional structure in a layerwise manner and the support material and the secondary support material have at least one common interface;
d) removal of the cured support material and the cured secondary support material by treatment with an aqueous medium.

13. The process according to claim 11, wherein the aqueous medium is an aqueous alkaline medium.

14. The process according to claim 11, wherein the viscosity of the object material is less than 20 MPas at 70° C.

15. The process according to claim 11, wherein the viscosity of the support material is less than 20 MPas at 70° C.

16. The process according to claim 11, wherein the support material is water-based.

17. The process according to claim 16, wherein the support material is free of nonaqueous solvents.

18. The process according to claim 16, wherein the aqueous medium in step d) has a pH which differs by at least 1 from the pH of the support material.

19. The process according to claim 11, wherein the free-radically curable compound is selected from the group consisting of monofunctional ethylenically unsaturated compounds, polyfunctional ethylenically unsaturated compounds and prepolymers.

20. The process according to claim 11, wherein the cationically polymerizable compound is selected from the group consisting of epoxides, oxetanes, oxazolines, lactones, lactams, vinyl ethers, furans, cyclic ketene acetals, spiroorthocarbonates and bicyclic orthoesters.
